(19) United States
(12) Patent Application Publication
(10) Pub. No.: US 2023/0311026 A1
(43) Pub. Date: Oct. 5, 2023

(54) LIQUID TRAP TANK AND METHOD FOR TRAPPING LIQUID

(71) Applicant: SEMES CO.,LTD., Cheonan-si (KR)

(72) Inventors: Arah CHO, Daejeon (KR); Jung Suk GOH, Hwaseong-si (KR); Jae Hoon PARK, Gwangju-si (KR); Hojin JANG, Cheonan-si (KR); Jung Yul LEE, Cheongju-si (KR); Kyungjin SEO, Asan-si (KR); Woo Sin JUNG, Cheonan-si (KR)

(73) Assignee: SEMES CO.,LTD., Cheonan-si (KR)

(21) Appl. No.: 18/152,485

(22) Filed: Jan. 10, 2023

(30) Foreign Application Priority Data
Mar. 30, 2022 (KR) 10-2022-0039652

(51) Int. Cl. B01D 19/00; H01L 21/67

(52) U.S. Cl. CPC B01D 19/0042; H01L 21/67017

(57) ABSTRACT

The present invention relates to a liquid trap tank and a method for trapping liquid, the liquid trap tank may include a tank body configured to have an accommodation space formed therein capable of accommodating a liquid, have an inflow unit formed in one portion thereof, and have a discharge unit formed in the other portion thereof, a first accommodation portion formed inside the tank body and configured to primarily and temporarily accommodate the liquid so that air bubbles are separated from the liquid introduced through the inflow unit, and a second accommodation portion formed inside the tank body and configured to secondarily and temporarily accommodate the liquid moved from the first accommodation portion or to discharge the moved liquid to the outside through the discharge unit.

### CROSS-REFERENCE TO RELATED APPLICATIONS

This application claims priority to and the benefit of Korean Patent Application No. 10-2022-0039652 filed in the Korean Intellectual Property Office on Mar. 30, 2022, the entire contents of which are incorporated herein by reference.

### TECHNICAL FIELD

The present invention relates to a semiconductor device, more specifically to a liquid trap tank and a method for trapping liquid.

### BACKGROUND ART

Various substrate processing devices are used for manufacturing semiconductor elements. Various liquids are used in these substrate processing devices. For example, cleaning liquid, distilled water, etchant, etc., are used to clean and etch the substrate, and a chemical such as a photoresist is used for photoresist coating on the substrate.

In the manufacture of semiconductor elements, such liquids may be supplied by using a separate liquid storage device in a manufacturing plant or a liquid storage bottle. As such, when the liquid is supplied to the substrate processing device or on the substrate, air bubbles may be included in the liquid. However, as the patterns of the semiconductor element gradually become smaller, these air bubbles adversely affect the quality of the semiconductor element. Therefore, it is necessary to suppress the generation of air bubbles in a liquid in the liquid supply system or to remove the air bubbles before the liquid is supplied on the substrate.

### SUMMARY

The present invention has been made in an effort to solve the above-mentioned problem, and an object of the present invention is to provide a liquid trap tank and a method for trapping liquid in which generation of air bubbles may be suppressed or air bubbles may be removed.

However, the object of the present invention is illustrative, and the scope of the present invention is not limited by the object.

A liquid trap tank according to the spirit of the present invention for solving the above-mentioned problems, may include: a tank body configured to have an accommodation space formed therein capable of accommodating a liquid, have an inflow unit formed in one portion thereof, and have a discharge unit formed in the other portion thereof; a first accommodation portion formed inside the tank body and configured to primarily and temporarily accommodate the liquid so that air bubbles are separated from the liquid introduced through the inflow unit; and a second accommodation portion formed inside the tank body and configured to secondarily and temporarily accommodate the liquid moved from the first accommodation portion or to discharge the moved liquid to the outside through the discharge unit.

According to the present invention, the liquid trap tank may further include: a separating wall unit formed between the first accommodation portion and the second accommodation portion so that the liquid overflows and moves to the second accommodation portion when the liquid is accommodated to a limit water level in the first accommodation portion and then exceeds the limit water level.

According to the present invention, the separating wall unit may be configured to have a first surface formed to correspond to the first accommodation portion, a top surface formed to be connected to the first surface, and a second surface formed to be connected to the top surface and correspond to the second accommodation portion.

According to the present invention, the second surface may include a flow guide unit for guiding a flow of the liquid so as to suppress generation of air bubbles caused by a sudden fall of the liquid overflowing from the top surface.

According to the present invention, the flow guide unit may be an inclined surface for preventing a sudden vertical fall of the liquid.

According to the present invention, the inclined surface may be one or more selected from: an equilibrium inclined surface having an overall constant inclination angle; a polygonal inclined surface having at least a plurality of inclination angles; a multi-stepped inclined surface in which two or more inclination angles are repeated; a parabolic inclined surface in which the inclination angle changes continuously from a sharp inclination angle to a gradual inclination angle; an S-shaped inclined surface having the inclination angles which alternatively change from a gradual inclination angle to a sharp inclination angle and then to a gradual inclination angle; a flow channel inclined surface in which a three-dimensional flow channel is formed; a pattern inclined surface; and combinations thereof.

According to the present invention, the flow guide unit may be a laminar flow guiding surface for guiding a laminar flow of the liquid.

According to the present invention, the laminar flow guiding surface may be one or more selected from: a horizontal row groove surface in which polygonal row grooves or rounded row grooves are formed in a horizontal direction; a vertical row groove surface in which polygonal row grooves or rounded row grooves are formed in a vertical direction; a flow channel forming surface in which a three-dimensional flow channel is formed; a dot-shaped concave-convex surface in which dot-shaped protrusion or groove portions are formed; a three-dimensional concave-convex surface in which three-dimensional protrusions or grooves are formed; a protrusion patterned surface; and combinations thereof.

In addition, according to the present invention, the first surface may be a vertical surface or an inverse inclined surface formed at the same angle as an inclined surface formed on the second surface.

According to the present invention, the top surface may be at least an equilibrium top surface which is of an entirely flat shape or a filter-type top surface in which protrusion portions or groove portions for filtering the air bubbles are formed.

According to the present invention, the inflow unit may be formed on a bottom surface or a lower portion of the first accommodation portion, and the discharge unit may be formed on a bottom surface or a lower portion of the second accommodation portion.

According to the present invention, the inflow unit may be formed on an upper portion or lateral surface of the first accommodation portion, and the discharge unit may be formed on a lower portion or bottom surface of the second accommodation portion.

According to the present invention, the inflow unit may be configured to have an extension pipe formed extending toward the first accommodation portion.

According to the present invention, the separating wall unit may be formed as high as a first height from the discharge unit so that the liquid is guided while falling in a direction of the discharge unit by gravity.

According to the present invention, the inflow unit may be connected to a liquid storage bottle storing the liquid, the discharge unit may be connected to a pumping unit for pumping the liquid into a substrate processing device.

According to the present invention, the liquid may include a photoresist chemical liquid.

According to the present invention, the liquid trap tank may further include a gas exhaust unit formed in the tank body and configured to exhaust gas generated from the separated air bubbles to the outside.

According to the present invention, the liquid trap tank may further include a ventilation unit formed in the tank body and configured to discharge an internal gas or the liquid to the outside and adjust a pressure of the accommodation space.

A method for trapping liquid according to the spirit of the present invention for solving the above-mentioned problems, may include: (a) supplying a liquid to the inside of a tank body through an inflow unit; (b) accommodating primarily and temporarily the liquid to a limit water level of a separating wall unit in a first accommodation portion formed inside the tank body so that air bubbles are separated from the liquid; and (c) guiding the liquid exceeding the limit water level of the separating wall unit to secondarily and temporarily accommodate the liquid in the second accommodation portion formed inside the tank body or discharging the moved liquid to the outside through a discharge unit.

Meanwhile, a liquid trap tank according to the spirit of the present invention for solving the above-mentioned problems, may include: a tank body configured to have an accommodation space formed therein capable of accommodating a liquid, have an inflow unit formed in one portion thereof, and have a discharge unit formed in the other portion thereof; a first accommodation portion formed inside the tank body and configured to primarily and temporarily accommodate the liquid so that air bubbles are separated from the liquid introduced through the inflow unit; a second accommodation portion formed inside the tank body and configured to secondarily and temporarily accommodate the liquid moved from the first accommodation portion or to discharge the moved liquid to the outside through the discharge unit; and a separating wall unit formed between the first accommodation portion and the second accommodation portion so that the liquid overflows and moves to the second accommodation portion when the liquid is accommodated to a limit water level in the first accommodation portion and then exceeds the limit water level, in which the separating wall unit may be configured to have a first surface formed to correspond to the first accommodation portion, a top surface formed to be connected to the first surface, and a second surface formed to be connected to the top surface and correspond to the second accommodation portion, the second surface may include a flow guide unit for guiding a flow of the liquid so as to suppress generation of the air bubbles caused by a sudden fall of the liquid overflowing from the top surface, the flow guide unit may be an inclined surface for preventing a sudden vertical fall of the liquid, the inflow unit may be formed on a bottom surface or a lower portion of the first accommodation portion, the discharge unit may be formed on a bottom surface or a lower portion of the second accommodation portion, and the separating wall unit may be formed as high as a first height from the discharge unit so that the liquid is guided while falling in a direction of the discharge unit by gravity.

According to various embodiments of the present invention configured as described above, it is possible to implement the effects of suppressing the generation of air bubbles or removing the air bubbles. Of course, the scope of the present invention is not limited by the effect.

### BRIEF DESCRIPTION OF THE DRAWINGS

FIG. 1 is a cross-sectional view illustrating a liquid trap tank according to some embodiments of the present invention.

FIG. 2 is a perspective view illustrating a separating wall unit of the liquid trap tank of FIG. 1.

FIG. 3 is an enlarged cross-sectional view illustrating the separating wall unit of the liquid trap tank of FIG. 1.

FIGS. 4A to 4F are cross-sectional views illustrating various embodiments of the separating wall unit of the liquid trap tank of FIG. 3.

FIGS. 5A to 5F are perspective views illustrating various embodiments of the separating wall unit of the liquid trap tank of FIG. 3.

FIGS. 6A to 6C are perspective views illustrating various embodiments of the separating wall unit of the liquid trap tank of FIG. 3.

FIG. 7 is a cross-sectional view illustrating the separating wall unit of the liquid trap tank according to some other embodiments of the present invention.

FIG. 8 is a cross-sectional view illustrating the liquid trap tank according to some or other embodiments of the present invention.

FIG. 9 is a conceptual view illustrating a liquid supply system in which the liquid trap tank of FIG. 1 is installed.

FIG. 10 is a flowchart illustrating a method for trapping liquid according to some embodiments of the present invention.

### DETAILED DESCRIPTION

Hereinafter, various embodiments of the present invention will be described in detail with reference to the accompanying drawings.

Embodiments of the present invention are provided to more completely explain the present invention to those skilled in the art. The following embodiments may be modified in various forms, and the scope of the present invention is not limited to the following embodiments. The embodiments are provided to make the present invention more thorough and complete and to completely convey the spirit of the present invention to those skilled in the art. In addition, a thickness or size of each layer illustrated in the drawings is exaggerated for the purpose of clarity and for convenience of description.

The terms used in the present specification are for explaining the particular embodiments, not for limiting the present invention. The singular expressions used in the present specification may include the plural expressions unless the context clearly dictates otherwise. The terms “comprise (include)” and/or “comprising (including)” used in the present specification are intended to specify the presence of the mentioned shapes, numbers, steps, operations, members, elements, and/or groups thereof, but do not exclude presence or addition of one or more other shapes, numbers, steps, operations, members, elements, and/or groups thereof.

Hereinafter, embodiments of the present invention will be described in detail with reference to the accompanying drawings. In the drawings, for example, depending on manufacturing techniques and/or tolerance, variations of the illustrated shape may be expected. Therefore, within the scope of the spirit of the present invention, embodiments should not be construed as being limited to a specific shape illustrated in the present specification, and should include, for example, a change in shape resulting in manufacturing.

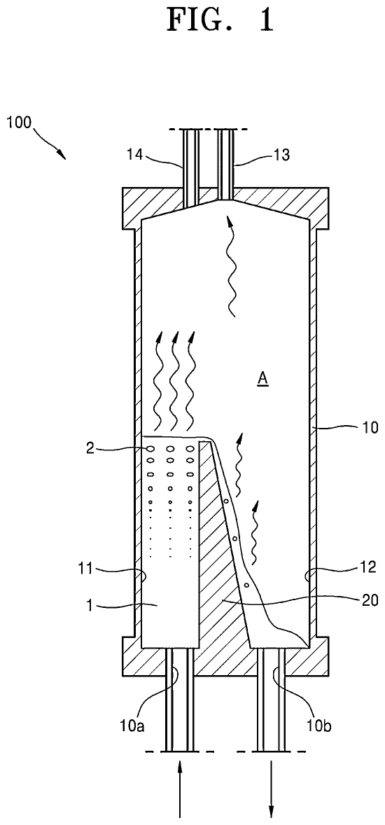

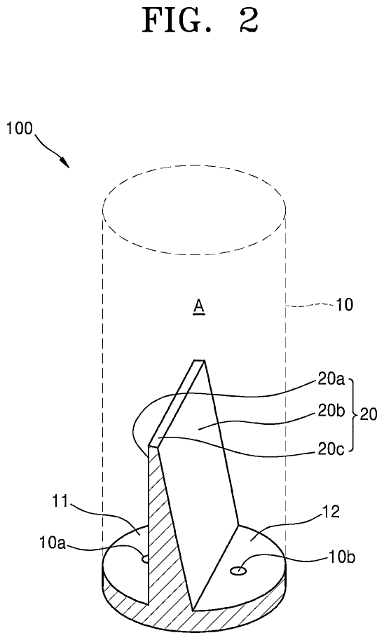

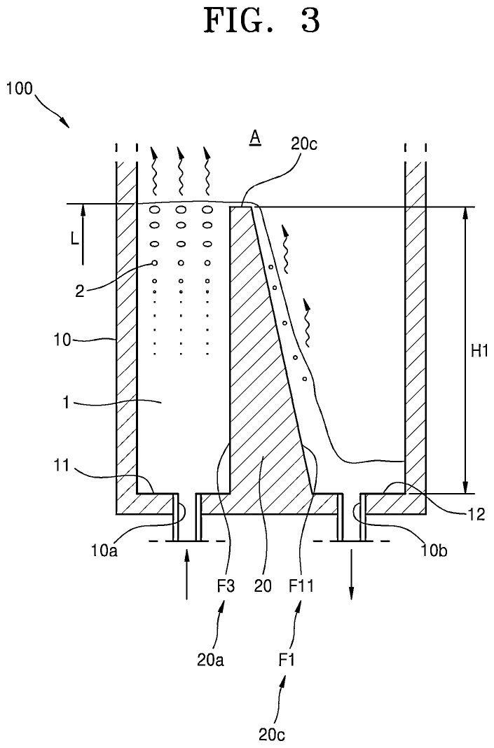

FIG. 1 is a cross-sectional view illustrating a liquid trap tank 100 according to some embodiments of the present invention, FIG. 2 is a perspective view illustrating a separating wall unit of the liquid trap tank 100 of FIG. 1, and FIG. 3 is an enlarged cross-sectional view illustrating the separating wall unit 20 of the liquid trap tank 100 of FIG. 1.

First, as illustrated in FIGS. 1 to 3, the liquid trap tank 100 according to some embodiments of the present invention may include a tank body 10, a first accommodation portion 11, a second accommodation portion 12, and a separating wall unit 20.

For example, the tank body 10 is configured to have an accommodation space A formed in the tank body 10 capable of accommodating liquid 1 therein, have an inflow unit 10a formed in one portion thereof, and have a discharge unit 10b formed in the other portion thereof. The tank body may be entirely formed in a cylindrical shaped structure having sufficient strength and durability to support the liquid 1 as well as the first accommodation portion 11, the second accommodation portion 12, and the separating wall unit 20.

Here, the liquid 1 may include a photoresist chemical liquid. However, the liquid 1 is not limited to the photoresist chemical liquid, and various kinds of chemical liquids used in the semiconductor process may all be applied.

The tank body 10 is not necessarily limited to the drawing, and in addition to the cylindrical shape, all other three-dimensional tubular structures such as an oval tube, a triangular tube, a square tube, or a polygonal tube may be applied.

In addition, for example, the first accommodation portion 11 is formed inside the tank body 10 and may be separated by the separating wall unit 20. That is, the first accommodation portion 11 may be one portion of the tank body 10 capable of primarily and temporarily accommodating the liquid 1 so that air bubbles 2 may be separated from the liquid 1 introduced through the inflow unit 10a.

In addition, for example, the second accommodation portion 12 is formed inside the tank body 10 and is a portion that may be separated by the separating wall unit 20. That is, the second accommodation portion 12 may be the other portion of the tank body 10 capable of secondarily and temporarily accommodating the liquid 1 moved from the first accommodation portion 11 or discharging the moved liquid 1 through the discharge unit 10b to the outside.

In addition, for example, the separating wall unit 20 may be a kind of wall structure formed between the first accommodation portion 11 and the second accommodation portion 12. When the liquid 1 is accommodated to a limit water level L in the first accommodation portion 11 and exceeds the limit water level L, it may overflow and move to the second accommodation portion 12.

Here, the separating wall unit 20 may be configured to have a first surface 20a formed corresponding to first accommodation portion 11, a top surface 20c formed to be connected to the first surface 20a, and a second surface 20b formed to be connected to the top surface 20c and corresponding to the second accommodation portion 12.

The second surface 20b may include a flow guide unit for guiding a flow of the liquid 1 so as to suppress the generation of the air bubbles 2 caused by a sudden fall of the liquid 1 overflowing from the top surface 20c.

For example, the flow guide unit may be an inclined surface F1 capable of reducing a falling speed of the liquid 1 in order to prevent a sudden vertical fall of the liquid 1.

More specifically, as illustrated in FIGS. 1 to 3, the inclined surface F1 may be an equilibrium inclined surface F11 which entirely has a constant inclination angle.

The inclination angle of the equilibrium inclined surface F11 may be 10 to 90 degrees with respect to the horizontal plane. However, the inclination angle of the equilibrium inclined surface F11 is not necessarily limited thereto, and may be formed at a wide variety of inclination angles.

In addition, for example, the inflow unit 10a may be formed on a bottom surface or a lower portion of the first accommodation portion 11, and the discharge unit 10b may be formed on a bottom surface or a lower portion of the second accommodation portion 12.

The separating wall unit 20 may be formed as high as a first height H1 from the discharge unit 10b so that the liquid 1 may be guided while falling in a direction of the discharge unit 10b by gravity.

Meanwhile, the liquid trap tank 100 according to some embodiments of the present invention may further include a gas exhaust unit 13 formed in the tank body 10 for exhausting gas generated from the separated air bubbles 2 to the outside, and a ventilation unit 14 formed in the tank body 10 for discharging an internal gas or the liquid to the outside to adjust a pressure of the accommodation space A.

Hereinafter, an operating process of the liquid trap tank 100 according to some embodiments of the present invention will be described with reference to FIGS. 1 to 3. The liquid 1 may be introduced from the lower portion of the tank body 10 through the inflow unit 10a formed on the bottom surface or the lower portion of the first accommodation portion 11.

Subsequently, the liquid 1 may be primarily accommodated to the first accommodation portion 11, and a water level of the liquid 1 may rise along the first surface 20a of the separating wall unit 20.

At this time, the pressure of the liquid 1 may be decreased from relatively high pressure to low pressure through the inflow unit 10a, which may cause the generation of the air bubbles 2 in the liquid 1.

Because the air bubbles 2 may adversely affect subsequent processes, the air bubbles 2 which is primarily and naturally generated in the first accommodation portion 11 may float, and the gas generated from the floating air bubbles 2 may be collected in the accommodation space A and discharged to the outside through the gas exhaust unit 13 or the ventilation unit 14.

Subsequently, when the water level of the liquid 1 rises along the first surface 20a of the separating wall unit 20 and then exceeds the limit water level L, the liquid 1 may overflow from the top surface 20c and move to the second accommodation portion 12 along the second surface 20b.

At this time, the liquid 1 falls comparatively slowly along the inclined surface F1 so that a falling speed of the liquid 1 may be reduced, thereby preventing a sudden vertical fall of the liquid 1. While the liquid 1 falls, the air bubbles 2 may easily float on a comparatively thin surface and be secondarily removed from the liquid 1.

Subsequently, the liquid 1 may be discharged to the outside through the discharge unit 10b formed on the bottom surface or lower portion of the second accommodation portion 12 in a state in which the air bubbles 2 is removed as much as possible

Therefore, it is possible to obtain an out-gassing effect which is to remove the air bubbles 2 inside the liquid 1 at constant exhaust environment using the gas exhaust unit 13 or the ventilation unit 14, thereby producing a high-quality product in the subsequent substrate processes.

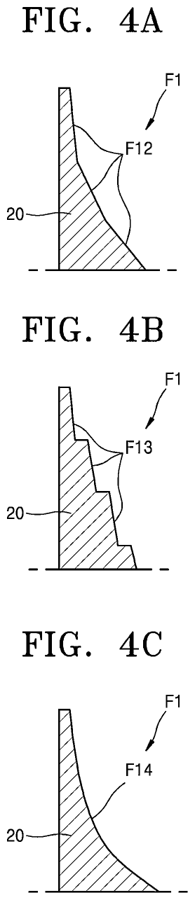

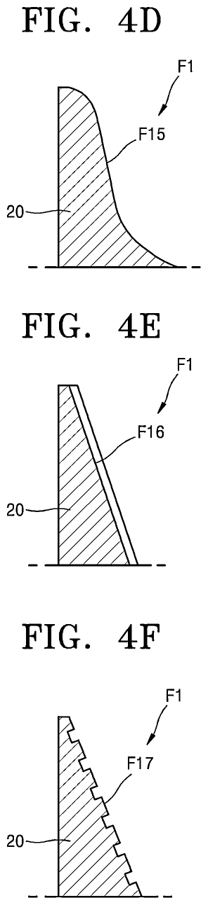

FIGS. 4A to 4F are cross-sectional views illustrating various embodiments of the separating wall unit 20 of the liquid trap tank 100 of FIG. 3.

As illustrated in FIGS. 4A to 4F, the inclined surface F1 of the liquid trap tank 100 according to some embodiments of the present invention may be applied as various types of inclined surfaces in addition to the equilibrium inclined surface F11 of FIG. 3 described above. The inclined surface F1 may include any one selected from the following various types or any one or more selected from combinations of the following various types: a polygonal inclined surface F12 illustrated in FIG. 4A having a plurality of inclination angles, a multi-stepped inclined surface F13 illustrated in FIG. 4B in which two or more inclination angles are repeated, a parabolic inclined surface F14 illustrated in FIG. 4C in which the inclination angle changes continuously from a sharp inclination angle to a gradual inclination angle, an S-shaped inclined surface F15 illustrated in FIG. 4D in which the inclination angles alternatively change from a gradual inclination angle to a sharp inclination angle and then to a gradual inclination angle, a flow channel inclined surface F16 illustrated in FIG. 4E where a three-dimensional flow channel is formed, and a pattern inclined surface F17 with various patterns illustrated in FIG. 4F.

Therefore, in consideration of the characteristics such as viscosity, permeability, and flowability of the liquid 1, it is possible to maximize a removal rate of the air bubbles 2 in the liquid 1 by optimizing a design of the various types of inclined surface F1.

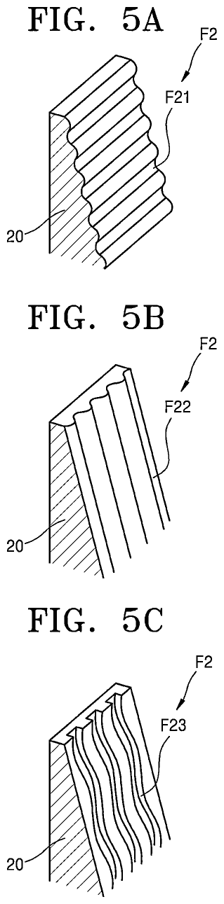

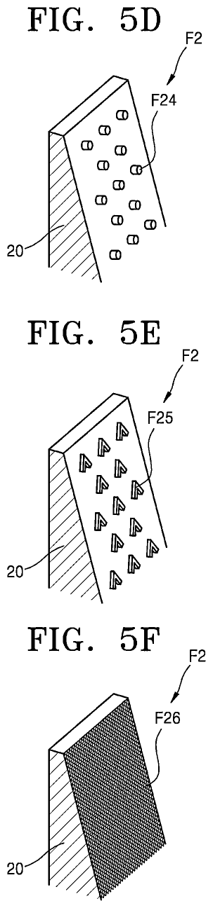

FIGS. 5A to 5F are perspective views illustrating various embodiments of the separating wall unit 20 of the liquid trap tank 100 of FIG. 3.

As illustrated in FIGS. 5A to 5F, the flow guide unit, not necessarily limited to the inclined surface, may be, for example, a laminar flow guiding surface F2 that widens a friction area to guide a laminar flow of the liquid 1, even though the flow guide unit is a vertical surface or an inclined surface.

The laminar flow guiding surface F2 may include any one selected from the following various types or any one or more selected from combinations of the following various types: a horizontal row groove surface F21 illustrated in FIG. 5A in which polygonal row grooves or rounded row grooves are formed in a horizontal direction; a vertical row groove surface F22 illustrated in FIG. 5B in which polygonal row grooves or rounded row grooves are formed in a vertical direction; a flow channel forming surface F23 illustrated in FIG. 5C in which a three-dimensional flow channel is formed; a dot-shaped concave-convex surface F24 illustrated in FIG. 5D in which dot-shaped protrusion or groove portions are formed; a three-dimensional concave-convex surface F25 illustrated in FIG. 5E in which three-dimensional protrusions or grooves are formed (inverted V-shaped, comb pattern, etc.); and a protrusion patterned surface F26 illustrated in FIG. 5F in which various protrusion patterns are formed.

Therefore, in consideration of the characteristics such as viscosity, permeability, and flowability of the liquid 1, optimizing the laminar flow guiding surface F2 of these various types allows to maximize the removal rate of the air bubbles 2 in the liquid 1.

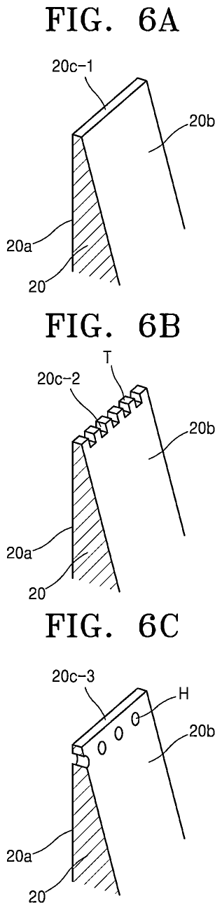

FIGS. 6A to 6C are perspective views illustrating various embodiments of the separating wall unit 20 of the liquid trap tank of FIG. 3.

As illustrated in FIGS. 6A to 6C, the top surface 20c of the separating wall unit 20 may include any one selected from the following various types or any one or more selected from combinations of the following various types: an equilibrium top surface 20c-1 illustrated in FIG. 6A which is of at least an entirely flat shape, a filter-type top surface 20c-2 illustrated in FIG. 6B in which a concave-convex portion T for filtering the air bubbles 2 are formed, and a perforated top surface 20c-3 illustrated in FIG. 6C in which perforated holes H for filtering the air bubbles 2 is formed. Also, the top surface 20c of the separating wall unit 20 may be one or more selected from various above-described types and combinations thereof.

Accordingly, the liquid 1 overflows along the top surface 20c of the separating wall unit 20 and may move to the second accommodation portion 12 in a flat form, or the air bubbles 2 may move to the second accommodation portion 12 along the concave-convex portion T in a filtered or destroyed form, or the bubble 2 may pass through the perforated holes H in a filtered or destroyed form and move to the second accommodation portion 12.

Therefore, the air bubbles 2 of the liquid 1 may also be removed from the top surface 20c of the separating wall unit 20.

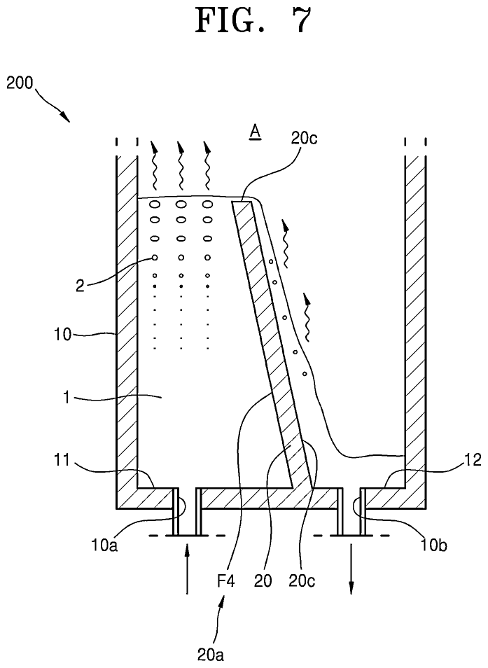

FIG. 7 is a cross-sectional view illustrating the separating wall unit 20 of the liquid trap tank 200 according to some other embodiments of the present invention.

As illustrated in FIG. 7, the first surface 20a of the separating wall unit 20 of the liquid trap tank 200 according to some other embodiments of the present invention is, in addition to the vertical surface F3 of FIGS. 1 to 6C, may be an inverse inclined surface F4 formed at the same angle as the inclined surface F1 formed on the second surface 20b, thereby maximizing the amount of the liquid 1 accommodated to the first accommodation portion 11.

Therefore, the separating wall unit 20 may also be installed inside the tank body 10 by making a panel of the same thickness inclined.

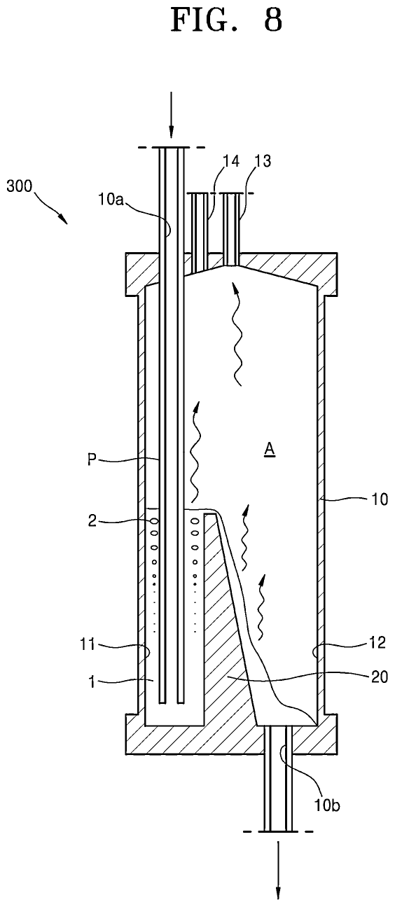

FIG. 8 is a cross-sectional view illustrating the liquid trap tank 300 according to some or other embodiments of the present invention.

As illustrated in FIG. 8, the liquid trap tank 300 according to some or other embodiments of the present invention, may be configured to have the inflow unit 10a formed on an upper portion or lateral surface of the first accommodation portion 11, and have the discharge unit 10b formed on a lower portion or bottom surface of the second accommodation portion 12.

At this time, the inflow unit 10a may be configured to have an extension pipe P formed therein and extending toward the first accommodation portion 11.

Therefore, the liquid 1 is introduced from an upper part of the tank body 10 through the inflow unit 10a formed on the upper portion or lateral surface of the first accommodation portion 11 and may be primarily accommodated to the first accommodation portion 11 along the extension pipe P.

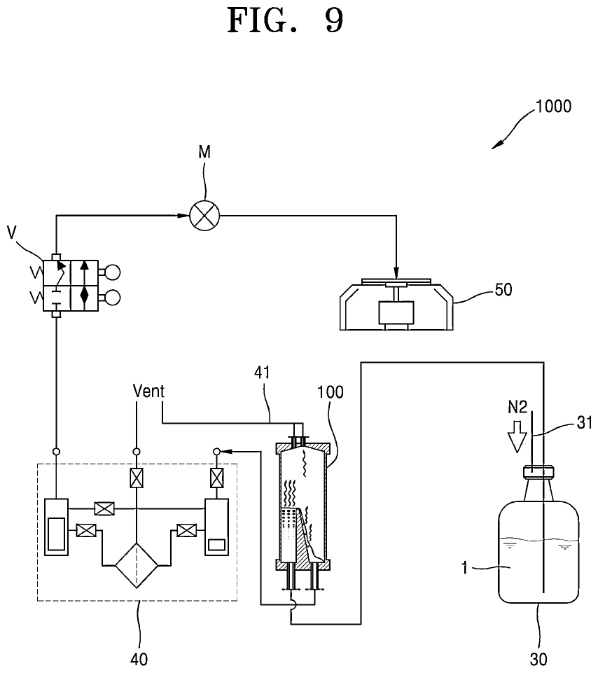

FIG. 9 is a conceptual view illustrating a liquid supply system 1000 in which the liquid trap tank 100 of FIG. 1 is installed.

As illustrated in FIG. 9, the inflow unit 10a of the liquid trap tank 100 of FIG. 1 may be connected to a liquid storage bottle 30 storing the liquid 1, and the discharge unit 10b may be connected to a pumping unit 40 for pumping the liquid 1 to the substrate processing device 50.

The liquid supply system 1000, including the liquid trap tank 100 of the present invention, may include the liquid storage bottle 30, the liquid trap tank 100, and the pumping unit 40.

More specifically, for example, the liquid storage bottle 30 stores liquid 1 and may be replaced by a bottle unit after use. Selectively, the liquid storage bottle 30 may be connected to a gas injection line 31 to pressurize and discharge the liquid 1.

The liquid trap tank 100 may be any one of the liquid trap tanks 100, 200, and 300 of FIGS. 1 to 9 described above. The pumping unit 40 may be provided to pump the liquid 1 from the liquid storage bottle 30 to the substrate processing device 50. For example, the discharge unit 10b of the liquid trap tank 100 may be connected to the pumping unit 40 for pumping the liquid 1 to the substrate processing device 50, and the inflow unit 10a of the liquid trap tank 100 may be connected to the liquid storage bottle 30 storing the liquid 1.

The liquid trap tank 100 may be interposed between the liquid storage bottle 30 and the pumping unit 40 and may store the liquid 1 supplied from the liquid storage bottle 30 before supplying the liquid 1 to the pump unit 40. For example, the liquid trap tank 100 may suppress the generation of air bubbles or remove the air bubbles when the liquid 1 is initially supplied from the liquid storage bottle 30 or when the liquid 1 in the liquid storage bottle 30 is completely used up and replaced. Accordingly, the liquid 1 in the liquid storage bottle 30 may be completely used up, thereby minimizing the remaining amount of the liquid 1.

A valve V and a flow meter M may be interposed between the pumping unit 40 and the substrate processing device 50. For example, the valve V may be provided as a suck-back valve for controlling a quantitative discharge of the liquid 1. When the pumping unit 40 is operated, a suction force may be transferred through the liquid trap tank 100 to the liquid storage bottle 30. Therefore, when the liquid 1 is pumped from the liquid trap tank 100 and delivered to the substrate processing device 50, the liquid 1 may be naturally provided from the liquid storage bottle 30 to the liquid trap tank 100 by the amount of discharging while a water level in the liquid trap tank 100 is reduced.

In some embodiments, when the water level in the liquid trap tank 100 is lowered and this suction power transfer is weakened, the liquid storage bottle 30 may inject an inert gas, such as nitrogen gas, through the gas injection line 31 to supply the liquid 1 from the liquid storage bottle 30 to the liquid trap tank 100.

In some embodiments, the liquid trap tank 100 may be connected to a venting line 41 for discharging air or the liquid 1. This venting line 41 may also be added to the liquid trap tanks 100, 200, and 300 described above. Additionally, this venting line 41 may also be connected to the pumping unit 40.

The substrate processing device 50 may be provided with various devices for processing a substrate using the liquid 1. For example, the substrate processing device 50 may include photo track equipment for spin-coating a photoresist chemical on a substrate with liquid 1. However, the scope of this disclosure is not limited to the photo track equipment, and may be variously used for the substrate processing using the liquid 1.

The above-described liquid supply system 1000 may supply the liquid 1 in which the generation of air bubbles is suppressed or air bubbles are removed to the substrate processing device 50 using the liquid trap tank 100 described above, thereby improving a substrate processing performance.

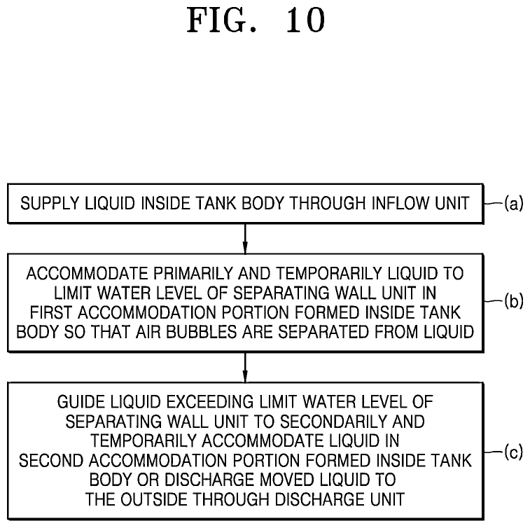

FIG. 10 is a flowchart illustrating a method of trapping liquid according to the embodiment of the present invention.

As illustrated in FIG. 10, a method for trapping liquid according to some embodiments of the present invention may include: (a) supplying the liquid 1 to the inside of the tank body 10 through the inflow unit 10a, (b) accommodating primarily and temporarily the liquid 1 to the limit water level L of the separating wall unit 20 in the first accommodation portion 11 formed inside the tank body 10 so that the air bubbles 2 may be separated from the liquid 10, and (c) guiding the liquid 1 exceeding the limit water level L of the separating wall unit 20 to secondarily and temporarily accommodate the liquid 1 in the second accommodation portion 12 formed inside the tank body 10 or discharging the moved liquid 1 to the outside through the discharge unit 10b.

Therefore, according to the method for trapping liquid of some embodiments of the present invention, a series of processes of: supplying the liquid 1 to the inside of the tank body 10 through the inflow unit 10a; and primarily and temporarily accommodating the liquid 1 to the limit water level L of the separating wall unit 20 at the first accommodation portion 11 formed inside the tank body 10 so that the air bubbles 2 may be separated from the liquid 1; and guiding the liquid 1 exceeding the limit water level L of the separating wall unit 20 to secondarily and temporarily accommodate the liquid 1 to the second accommodation portion 12 formed inside the tank body 10 or discharging the moved liquid 1 to the outside through the discharge unit 10b, may be performed.

While the present invention has been described with reference to the embodiment illustrated in the drawings, the embodiment is described just for illustration, and those skilled in the art to which the present invention pertains will understand that various modifications of the embodiment and any other embodiment equivalent thereto are available. Accordingly, the true technical protection scope of the present invention should be determined by the technical spirit of the appended claims.

What is claimed is:

1. A liquid trap tank comprising:
a tank body configured to have an accommodation space formed therein capable of accommodating a liquid, have an inflow unit formed in one portion thereof, and have a discharge unit formed in the other portion thereof;
a first accommodation portion formed inside the tank body and configured to primarily and temporarily accommodate the liquid so that air bubbles are separated from the liquid introduced through the inflow unit; and
a second accommodation portion formed inside the tank body and configured to secondarily and temporarily accommodate the liquid moved from the first accommodation portion or to discharge the moved liquid to the outside through the discharge unit.

2. The liquid trap tank of claim 1, further comprising:
a separating wall unit formed between the first accommodation portion and the second accommodation portion so that the liquid overflows and moves to the second accommodation portion when the liquid is accommodated to a limit water level in the first accommodation portion and then exceeds the limit water level.

3. The liquid trap tank of claim 2, wherein the separating wall unit is configured to have a first surface formed to correspond to the first accommodation portion, a top surface formed to be connected to the first surface, and a second surface formed to be connected to the top surface and correspond to the second accommodation portion.

4. The liquid trap tank of claim 3, wherein the second surface comprises a flow guide unit for guiding a flow of the liquid so as to suppress generation of air bubbles due to a sudden fall of the liquid overflowing from the top surface.

5. The liquid trap tank of claim 4, wherein the flow guide unit is an inclined surface for preventing a sudden vertical fall of the liquid.

6. The liquid trap tank of claim 5, wherein the inclined surface is one or more selected from an equilibrium inclined surface having an overall constant inclination angle, a polygonal inclined surface having at least a plurality of inclination angles, a multi-stepped inclined surface in which two or more inclination angles are repeated, a parabolic inclined surface in which the inclination angle changes continuously from a sharp inclination angle to a gradual inclination angle, an S-shaped inclined surface having the inclination angles which alternatively change from a gradual inclination angle to a sharp inclination angle and then to a gradual inclination angle, a flow channel inclined surface in which a three-dimensional flow channel is formed, a pattern inclined surface, and combinations thereof.

7. The liquid trap tank of claim 4, wherein the flow guide unit is a laminar flow guiding surface for guiding a laminar flow of the liquid.

8. The liquid trap tank of claim 7, wherein the laminar flow guiding surface is one or more selected from a horizontal row groove surface in which polygonal row grooves or rounded row grooves are formed in a horizontal direction, a vertical row groove surface in which polygonal row grooves or rounded row grooves are formed in a vertical direction, a flow channel forming surface in which a three-dimensional flow channel is formed, a dot-shaped concave-convex surface in which dot-shaped protrusion or groove portions are formed, a three-dimensional concave-convex surface in which three-dimensional protrusions or grooves are formed, a protrusion patterned surface, and combinations thereof.

9. The liquid trap tank of claim 3, wherein the first surface is a vertical surface or an inverse inclined surface formed at the same angle as an inclined surface formed on the second surface.

10. The liquid trap tank of claim 3, wherein the top surface is one or more selected from an equilibrium top surface which is of an entirely flat shape, a filter-type top surface in which a concave-convex portion for filtering the air bubbles is formed, a perforated top surface in which perforated holes for filtering the air bubbles is formed, and combinations thereof.

11. The liquid trap tank of claim 2, wherein the inflow unit is formed on a bottom surface or a lower portion of the first accommodation portion, and the discharge unit is formed on a bottom surface or a lower portion of the second accommodation portion.

12. The liquid trap tank of claim 2, wherein the inflow unit is formed on an upper portion or lateral surface of the first accommodation portion, and the discharge unit is formed on a lower portion or bottom surface of the second accommodation portion.

13. The liquid trap tank of claim 12, wherein the inflow unit is configured to have an extension pipe formed therein and extending toward the first accommodation portion.

14. The liquid trap tank of claim 2, wherein the separating wall unit is formed as high as a first height from the discharge unit so that the liquid is guided while falling in a direction of the discharge unit by gravity.

15. The liquid trap tank of claim 2, wherein the inflow unit is connected to a liquid storage bottle storing the liquid, the discharge unit is connected to a pumping unit for pumping the liquid into a substrate processing device.

16. The liquid trap tank of claim 1, wherein the liquid comprises a photoresist chemical.

17. The liquid trap tank of claim 1, further comprising:
a gas exhaust unit formed in the tank body and configured to exhaust gas generated from the separated air bubbles to the outside.

18. The liquid trap tank of claim 1, further comprising:
a ventilation unit formed in the tank body and configured to discharge an internal gas or the liquid to the outside to adjust a pressure of the accommodation space.

19. A method for trapping liquid, the method comprising:
(a) supplying a liquid to the inside of a tank body through an inflow unit;
(b) accommodating primarily and temporarily the liquid to a limit water level of a separating wall unit in a first accommodation portion formed inside the tank body so that air bubbles are separated from the liquid; and
(c) guiding the liquid exceeding the limit water level of the separating wall unit to secondarily and temporarily accommodate the liquid in the second accommodation portion formed inside the tank body or discharging the moved liquid to the outside through a discharge unit.

20. A liquid trap tank comprising:
a tank body configured to have an accommodation space formed therein capable of accommodating a liquid, have an inflow unit formed in one portion thereof, and have a discharge unit formed in the other portion thereof;
a first accommodation portion formed inside the tank body and configured to primarily and temporarily accommodate the liquid so that air bubbles are separated from the liquid introduced through the inflow unit;
a second accommodation portion formed inside the tank body and configured to secondarily and temporarily accommodate the liquid moved from the first accommodation portion or to discharge the moved liquid to the outside through the discharge unit; and
a separating wall unit formed between the first accommodation portion and the second accommodation portion so that the liquid overflows and moves to the second accommodation portion when the liquid is accommodated to a limit water level in the first accommodation portion and then exceeds the limit water level,
wherein the separating wall unit is configured to have a first surface formed to correspond to the first accommodation portion, a top surface formed to be connected to the first surface, and a second surface formed to be connected to the top surface and correspond to the second accommodation portion, the second surface comprises a flow guide unit for guiding a flow of the liquid so as to suppress generation of the air bubbles caused by a sudden fall of the liquid overflowing from the top surface, the flow guide unit is inclined surface for preventing a sudden vertical fall of the liquid, the inflow unit is formed on a bottom surface or a lower portion of the first accommodation portion, the discharge unit is formed on a bottom surface or a lower portion of the second accommodation portion, and the separating wall unit is formed as high as a first height from the discharge unit so that the liquid is guided while falling in a direction of the discharge unit by gravity.
